(19) United States
(12) Patent Application Publication
(10) Pub. No.: US 2026/0276193 A1
(43) Pub. Date: Sep. 17, 2026

(54) SYSTEM FOR CAPTURING WASTE HEAT FROM A THERMAL INCINERATOR

(71) Applicant: Compressed Energy Systems, LLC, Eldorado, IL (US)

(72) Inventor: Christopher E. SCHIMP, Eldorado, IL (US)

(21) Appl. No.: 19/564,717

(22) Filed: Mar. 12, 2026

Related U.S. Application Data
(60) Provisional application No. 63/771,289, filed on Mar. 13, 2025.

(51) Int. Cl. F23G 7/06; H10N 10/10

(52) U.S. Cl. CPC F23G 7/065; H10N 10/10; F23G 2206/203

(57) ABSTRACT

A system for capturing waste heat to generate electrical power includes a thermal incinerator including a gas vessel tower having an open interior and an exterior shell, in which the thermal incinerator may substantially incinerate harmful air pollutants. A plurality of thermal electrical generators are wrapped about the exterior shell of the thermal incinerator, wherein the thermal electrical generators generate electrical power supplied to a power storage for storing the electrical power from the thermal electrical generators.

### CROSS-REFERENCE TO RELATED APPLICATIONS

This application claims priority to U.S. Provisional Patent Application No. 63/771,289, filed on Mar. 13, 2025, the contents of which are incorporated herein by reference in its entirety.

### TECHNICAL FIELD

The present disclosure is generally directed to capturing and utilizing waste heat for use in generating electricity.

### BACKGROUND

Industrial sites including biogas production facilities must destroy the waste byproduct gas after cleaning the raw gas. In many instances, this destruction occurs via the use of a thermal incinerator is used. A thermal incinerator is a type of air pollution control equipment used in industrial processes to reduce emissions of volatile organic compounds (VOCs), odors, harmful air pollutants (HAPs), and other greenhouse gases (GHG) before releasing them into the atmosphere.

There is a need to make economical use out of the heat generated from a thermal incinerator such as the generation of useful electrical power.

### BRIEF DESCRIPTION OF DRAWINGS

FIG. 1 is a schematic diagram of a thermal incinerator for destroying harmful air pollutants;

FIG. 2 is a schematic diagram of a system for capturing waste heat from a thermal incinerator to generate electrical power;

FIG. 3 is a schematic diagram of a system for capturing waste heat from a thermal incinerator to generate electrical power to a bitcoin mining system; and

FIG. 4 is a schematic diagram of another embodiment of a system for capturing waste heat from a thermal incinerator to generate electrical power

For simplicity and clarity of illustration, the drawing illustrates the general manner of construction, and descriptions and details of well-known features and techniques may be omitted to avoid unnecessarily obscuring the present disclosure. Additionally, elements in the drawing are not necessarily drawn to scale. For example, the dimensions of some of the elements in the figures may be exaggerated relative to other elements to help improve understanding of embodiments of the present disclosure.

The terms “include,” and “have,” and any variations thereof, are intended to cover a non-exclusive inclusion, such that a process, method, system, article, device, or apparatus that comprises a list of elements is not necessarily limited to those elements but may include other elements not expressly listed or inherent to such process, method, system, article, device, or apparatus.

The terms “top,” “bottom,” “upper,” “lower,” and the like in the description and in the claims, if any, are used for descriptive purposes and not necessarily for describing permanent relative positions. It is to be understood that the terms so used are interchangeable under appropriate circumstances such that the embodiments of the system and/or methods described herein are, for example, capable of operation in other orientations than those illustrated or otherwise described herein.

### DETAILED DESCRIPTION OF EXEMPLARY EMBODIMENTS

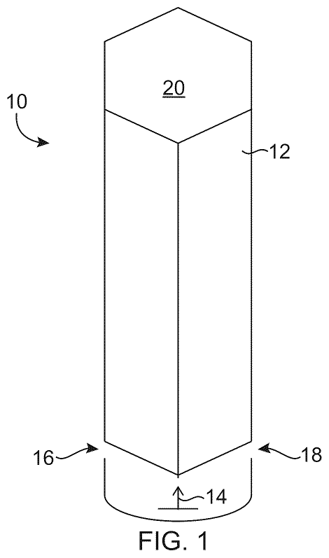

FIG. 1 is a schematic view of a thermal incinerator 10, which includes a gas vessel tower 12 having an open interior that may take on different diameters and heights and may be fabricated from stainless steel. The interior of the gas tower 12 includes a flame device 14 or other source of combustion or heat for incinerating harmful air pollutants (HAPs) 16, such as volatile organic compounds (VOCs), odors, greenhouse gases (GHG), and the like. A supplemental source of gas 18, such as methane, is introduced into the gas tower 12 to feed the flame device 14. Upon incineration of the harmful air pollutants 16, remaining gasses are vented to the atmosphere, such as through exhaust port 20.

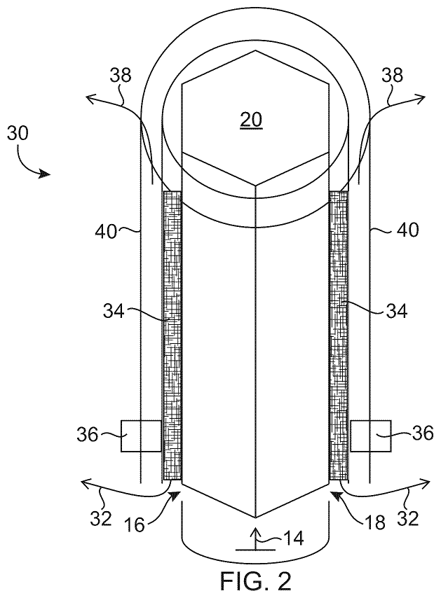

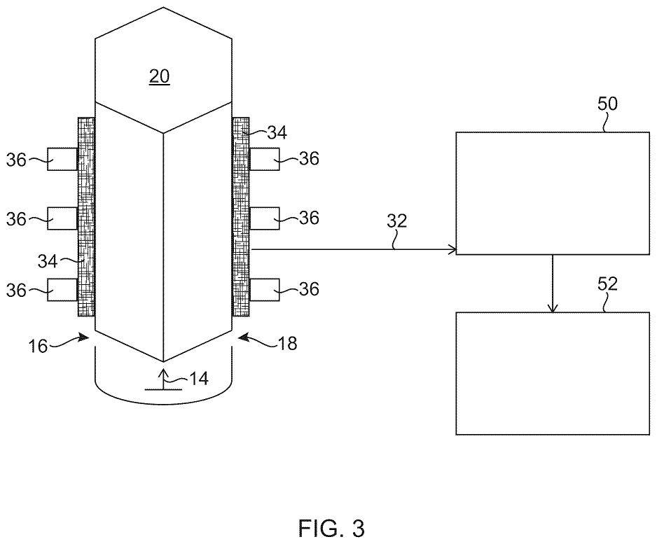

FIG. 2 illustrates a system 30 for capturing waste heat from a thermal incinerator to generate electrical power. The exterior perimeter of the gas tower 12 may be wrapped with layers of thermal electric generators 34. The tower 12 may take on a number of shapes such as a circle or oval or, preferably, a shape having relatively flat surfaces such as a hexagon, octagon, rectangular, square, etc. Moreover, the tower 12 may be hexagon along the majority of its length with the lower portion of the tower 12 near the flame device 14 round. The thermal electric generators 34 produce electrical power due to the temperature difference between the hot and cold side of the generators 34. The outer perimeter of the incinerator may reach up to a temperature in a range of about 500 to 1500 degrees such that heat will transfer through the interior side of thermal electric generators 34. The exterior side of the generators 34 may be cooled by circulating ambient air or via the circulation of water through coils. In the embodiment shown in FIG. 2, ambient air is circulated via fans 36 through a channel formed between the generators 34 and an outer shell 40 before venting through an exhaust port 38.
FIG. 3 illustrates an alternative embodiment which uses a plurality of fans 36 or other forms of cooling devices located along the length of the layers of thermal electrical generators 34, which may obviate the need for a separate ventilation channel formed by an outer shell 40.

The electrical power 32 generated by the thermal electrical generators 34, which may be direct current voltage, may be fed to a form of power storage 50, such as a battery pack or a battery energy storage system. The power storage 50 may act as a power supply to a bitcoin mining system 52. The addition of the power storage 50 between the incinerator wrapped with thermal electrical generators and the bitcoin mining system 52, stabilized by the power storage 50 allows the thermal incinerator to operate as a battery charger.

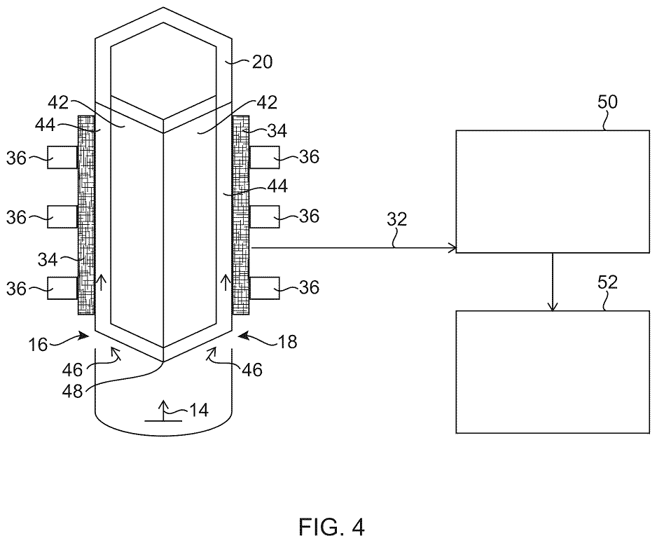

FIG. 4 illustrates another embodiment a system for capturing waste heat from a thermal incinerator to generate electrical power. In this embodiment, the thermal incinerator includes an inner tube 42 forming an annular flow path 44 between the exterior of the inner tube 42 and the interior or inner surface of the gas tower 12. The inner tube 42 may take on a number of different geometric forms such as one in which its lower portion is shaped into a pyramid-like or bullet-like shape forming a nozzle having a point 48. The flame device is located below the inner tube 42 such that the heat 46 is directed into and dispersed through the annular flow path 44. By increasing the size of the diameter of the gas tower 12 and incorporating an inner tube 42, thus increasing the surface area in which the heat contacts, the thermal electric generators 34 are exposed to a reduced level of heat. In addition, the larger diameter of the gas tower 12 coupled with the inner tube 42 allows for an increase in the volume of the exhaust to exit to the atmosphere without any additional resistance. The inner tube 42 may be adjustably installed within the gas tower 12 by, for example, bolts placed along various locations within the gas tower 12. Thus, the inner tube 42 may be adjusted vertically to adjust the distance between the flame device and the inner tube 42, to adjust where the supplemental source of gas 18 is introduced with respect to the inner tube 42 and/or where the harmful air pollutants 16 are introduced with respect to the inner tube 42. The vertical location of the inner tube 42 may be adjusted based on the composition of the harmful air pollutants 16 and/or the supplemental source of gas 18.

While various novel features of the invention have been shown, described, and pointed out as applied to particular embodiments thereof, it should be understood that various omissions, substitutions and changes in the form and details of the systems and methods described and illustrated may be made by those skilled in the art without departing from the spirit of the invention.

For example, the power generated not only can be used for bitcoin mining but also can be connected to the power grid creating renewable energy from the thermal incinerator electricity generation from biogas facilities that incinerate biogenic hydrogen sulfide and waste biogenic methane, The electricity produced from renewable energy receives substantially revenue from the power utilities.

Moreover, the particular system components are for illustrative purposes to facilitate a full and complete understanding and appreciation of the various aspects and functionality of particular embodiments of the invention, as realized in system and method embodiments thereof. Those skilled in the art will appreciate that the invention can be practiced in other than the described embodiments, which are presented for purposes of illustration and not limitation.

What is claimed is:

1. A system for capturing waste heat to generate electrical power comprising:
a thermal incinerator including a gas vessel tower having an open interior and an exterior shell, wherein the thermal incinerator may substantially incinerate harmful air pollutants;
a plurality of thermal electrical generators wrapped about the exterior shell of the thermal incinerator, wherein the thermal electrical generators generate electrical power;
a cooling source for cooling the thermal electrical generators; and
a power storage receiving and storing the electrical power from the thermal electrical generators.

2. The system of claim 1 wherein the thermal incinerator includes a flame device as a source of heat for thermally incinerating the harmful air pollutants.

3. The system of claim 2 further comprising a supplemental source of gas introduced into the gas vessel tower to feed the flame device.

4. The system of claim 1 further comprising an exhaust port for venting gasses outside of the gas vessel tower.

5. The system of claim 1 further comprising:
an outer shell surrounding the plurality of thermal electrical generators; and
a plurality of fans for circulating ambient air through a channel formed between the thermal electric generators and the outer shell.

6. The system of claim 1 further comprising an inner tube within the gas vessel tower forming an annular flow path between an exterior of the inner tube and the interior of the gas vessel tower.

7. The system of claim 6 wherein the inner tube has a pyramid-like shape having a point on a lower end.

8. The system of claim 7 further comprising a flame device as a source of heat for thermally incinerating the harmful air pollutants and wherein the flame device is located below the point of the inner tube such that heat from the flame device is directed into and dispersed through the annular flow path.

9. The system of claim 8 wherein the inner tube may be adjusted in a vertical direction such that the inner tube may be placed closer to or farther away from the flame device.

10. The system of claim 1 further comprising a bitcoin mining system powered by the stored electrical power.
